(19) United States
(12) Patent Application Publication
(10) Pub. No.: US 2026/0362724 A1
(43) Pub. Date: Nov. 12, 2026

(54) ZERO-BIAS RESONANT GRAPHENE/MOS2 MID-INFRARED RECTIFIER

(71) Applicant: Jonathan Washburn, Austin, TX (US)

(72) Inventor: Jonathan Washburn, Austin, TX (US)

(21) Appl. No.: 19/675,367

(22) Filed: May 12, 2026

Related U.S. Application Data
(60) Provisional application No. 63/804,580, filed on May 12, 2025.

(51) Int. Cl. H10D 8/75; H01Q 1/24; H01Q 9/16; H10D 8/01; H10D 62/80; H10D 64/62

(52) U.S. Cl. CPC H10D 8/755; H01Q 1/248; H01Q 9/16; H10D 8/053; H10D 62/883; H10D 64/62

(57) ABSTRACT

A zero-bias resonant-tunnelling diode rectifies mid-infrared photons without externally applied bias. The diode includes a first graphene electrode of a first doping type, a second graphene electrode of an opposite doping type, and a few-layer MoS2 barrier disposed between the electrodes. Built-in asymmetry between the electrodes positions a quantized resonant sub-band such that incident mid-infrared photons aligned to the resonant sub-band drive photon-assisted resonant tunnelling through the barrier and generate DC current. In preferred embodiments, a three-layer MoS2 barrier places the resonant sub-band near 88 meV for operation near 14 um. The diode may be coupled to an antenna to form a rectenna pixel and may be tiled into arrays for harvesting, sensing, or detector applications. Barrier layer count and thickness may be selected to tune the resonant condition to different mid-infrared bands. In further embodiments, design relationships associated with selected resonant conditions may be formally represented and machine-verified.

### CROSS-REFERENCE TO RELATED APPLICATIONS

This application claims the benefit of and priority to U.S. Provisional Patent Application No. 63/804,580, filed on May 12, 2025, the entirety of which is incorporated herein by reference.

### BACKGROUND

The present disclosure relates generally to high-frequency rectification and solid-state energy conversion. More particularly, the present disclosure relates to zero-bias resonant-tunnelling diode structures configured to rectify mid-infrared photons by photon-assisted tunnelling through a resonant sub-band in a few-layer van der Waals barrier. In preferred embodiments, the disclosure further relates to graphene/MoS2/graphene resonant-tunnelling structures, antenna-coupled rectenna pixels, wavelength-tuned resonant design, array implementations, and proof-assisted design verification.

Rectification of electromagnetic radiation in the mid-infrared band is desirable for applications including waste-heat recovery, passive sensing, compact self-powered electronics, and related solid-state power-conversion functions. Thermal radiation from many practical sources occupies wavelengths in or near the mid-infrared, and the atmospheric window around 8 um to 14 um is particularly relevant to useful propagation and collection of thermal radiation.

Conventional approaches, however, suffer from substantial limitations at the frequencies of interest. Metal-insulator-metal diodes are constrained by junction capacitance and series resistance, which can limit effective cutoff performance in the target band. Schottky diodes are likewise limited by transit-time and depletion-region constraints at higher terahertz frequencies. Bolometric detectors operate by heating and sensing a thermal response, rather than directly rectifying incident photons to produce DC electrical output. Symmetric graphene junctions, although capable of supporting very fast carrier transport, do not provide useful zero-bias rectification because symmetric electrode conditions produce no net rectified current at zero applied bias.

Accordingly, there remains a need for a compact solid-state device that directly rectifies mid-infrared photons to DC current, operates without externally applied bias, preserves useful bandwidth in the target frequency range, and can be implemented as a stand-alone diode, an antenna-coupled rectenna pixel, or a tiled array architecture. There is a further need for a device architecture in which a resonant tunnelling condition can be tuned to a selected mid-infrared target band, including in preferred embodiments a target band near about 14 um.

In preferred embodiments of the present disclosure, the target resonant energy is placed near a coherence energy identified as E_coh=phi\hat{ }-5, corresponding to approximately 13.8 um to 14 um, and selected relationships used by the preferred embodiment may be formally represented and machine-verified. However, the core inventive mechanism is not the abstract recognition framework itself, but rather a zero-bias resonant mid-infrared rectifier in which built-in asymmetry and a quantized resonant sub-band cooperate to produce photon-assisted tunnelling and DC output without external bias.

### SUMMARY

The present disclosure provides a zero-bias resonant-tunnelling diode configured to rectify mid-infrared photons without application of an external bias voltage. In broad form, the diode includes a first graphene electrode of a first doping type, a second graphene electrode of an opposite doping type, and a few-layer MoS2 quantum-well barrier disposed between the electrodes. The built-in asymmetry between the electrodes positions a quantized resonant sub-band in the barrier such that incident mid-infrared photons having energy aligned to the resonant sub-band drive photon-assisted resonant tunnelling and generate DC current without external bias.

In one aspect, the disclosure provides a zero-bias mid-infrared rectifier in which a first carrier population in the first graphene electrode and a second carrier population in the second graphene electrode are intentionally made asymmetric by opposite doping polarity and/or by different electrostatic or chemical doping conditions. This asymmetry establishes a non-zero built-in potential difference and causes the resonant tunnelling condition to produce net rectified current at zero applied bias when the device is illuminated in a target mid-infrared band.

In another aspect, the disclosure provides a resonant barrier structure in which the MoS2 barrier thickness is used to tune the resonant sub-band energy. In a preferred embodiment, a three-layer MoS2 barrier having a thickness of about 1.8 nm to about 2.0 nm places the resonant sub-band near about 88 meV, thereby targeting photons at approximately 14 um. In alternative embodiments, different barrier layer counts shift the resonant sub-band to shorter-wavelength or longer-wavelength target bands. Thus, barrier layer count and/or barrier thickness may be used as a design variable for selecting a target operating wavelength band.

In a preferred device embodiment, the diode includes a p-doped monolayer graphene emitter, a three-layer MoS2 barrier, and an n-doped monolayer graphene collector. In that preferred embodiment, the built-in asymmetry is about 87 meV, the resonant sub-band is near about 88 meV, and the device is configured for zero-bias rectification of approximately 14 um radiation at room temperature. In a demonstrated implementation described in the disclosure, the preferred device structure provides measured zero-bias responsivity at 300 K under 14 um CW illumination.

In a further aspect, the disclosure provides an antenna-coupled rectenna pixel in which the zero-bias resonant-tunnelling diode is electrically coupled to a mid-infrared antenna, such as a dipole antenna, to improve coupling of incident radiation into the diode. In preferred embodiments, antenna impedance and diode input characteristics are selected so that the antenna-coupled pixel operates as a compact rectifying unit suitable for stand-alone use or for integration into a tiled array.

In another aspect, the disclosure provides tiled arrays of such rectifying pixels. The array embodiments may be configured for waste-heat harvesting, focal-plane-array imaging, sensing, power scavenging, or related downstream functions. In some embodiments, outputs from multiple pixels may be buffered, accumulated, level-shifted, regulated, charge-pumped, or otherwise conditioned to provide a useful downstream power or signal output. These system-level embodiments remain subordinate to the core rectification mechanism, which resides in the zero-bias asymmetric resonant-tunnelling diode structure itself.

In a preferred doctrinal embodiment, the resonant condition is aligned to a coherence energy identified as E_coh=phi\hat{ }-5, corresponding to approximately 13.8 um to 14 um. In that preferred embodiment, the near-14 um resonant condition, atmospheric-window correspondence, asymmetry positivity, and selected impedance or design relations may be formally represented and machine-verified. Such formal representation and machine verification are used as strategic support for selected embodiments and claim families, including preferred design-verification and software-related embodiments, but do not alter the underlying physical identity of the invention as a zero-bias resonant mid-infrared rectifier.

In still further aspects, the disclosure provides methods of rectifying mid-infrared radiation, methods of designing or selecting resonant-tunnelling diode geometries for a target wavelength band, methods of fabricating the disclosed structures, and computer-implemented workflows for selecting barrier thickness, resonant energy, electrode asymmetry, antenna geometry, and related parameters. In selected embodiments, these workflows further include verification steps that compute or confirm resonance proximity, matching efficiency, bandwidth criteria, expected output performance, and/or formal proof-assisted design acceptance conditions prior to fabrication.

Accordingly, the present disclosure provides a broad but disciplined non-provisional disclosure centered on a zero-bias asymmetric graphene/MoS2/graphene resonant-tunnelling rectifier, while preserving narrower preferred embodiments directed to approximately 14 um operation, preferred coherence-energy alignment, antenna-coupled rectenna pixels, tiled arrays, output-conditioning architectures, proof-assisted verification workflows, and downstream harvesting, imaging, and sensing systems.

Where numerical values are provided, the disclosure distinguishes demonstrated device-level measurements, modeled or calculated design points, and prophetic system-level deployments. For example, measured or characterized diode parameters may include zero-bias responsivity, dynamic resistance, junction capacitance, and target-band operation, while modeled pixel or array outputs may use those measured or characterized values together with antenna-coupling, source-flux, buffering, or interconnect assumptions. Formal representation or machine verification of selected relationships may certify mathematical or design-rule consistency, but does not by itself substitute for empirical measurement of a fabricated device unless expressly stated.

### BRIEF DESCRIPTION OF FIGURES

FIG. 1 is a cross-sectional schematic view of a zero-bias resonant-tunnelling diode including a first graphene electrode, a few-layer MoS2 quantum-well barrier, a second graphene electrode, a substrate, and an optional encapsulation structure.

FIG. 2 is an energy-band and operating-state diagram illustrating built-in electrode asymmetry, a resonant sub-band in the barrier, photon-assisted tunnelling, and zero-bias DC current generation.

FIG. 3 is a top plan schematic view of an antenna-coupled rectenna pixel including a dipole antenna structure, a diode region, and pixel layout features.

FIG. 4 is a spectral alignment diagram illustrating a preferred operating band, an atmospheric window, a thermal spectrum, and a preferred resonance/wavelength correspondence near approximately 14 um.

FIG. 5 is a fabrication workflow diagram illustrating substrate preparation, first graphene transfer, barrier transfer, second graphene transfer, antenna and contact formation, encapsulation, and packaging.

FIG. 6 is an equivalent-circuit and impedance-matching diagram illustrating antenna coupling, diode resistance, diode capacitance, optional tuning structure, and buffered DC output.

FIG. 7 is an array architecture diagram illustrating a tiled plurality of rectenna pixels, interconnect paths, and output aggregation structures.

FIG. 8 is a focal-plane-array implementation diagram illustrating a pixel array region, pixel pitch, a readout integrated circuitry interface, and detector packaging features.

FIG. 9 is a multi-band sensing embodiment diagram illustrating reference and gas-band pixel groups, ratio processing, and sensor output generation.

FIG. 10 is a thermoradiative embodiment diagram illustrating a sky-facing array, a warm-side environment, a cold-sky environment, radiative exchange, and output delivery.

FIG. 11 is a design and verification workflow diagram illustrating target-band input, barrier-selection logic, asymmetry evaluation, bandwidth evaluation, matching evaluation, performance estimation, optional formal verification, and design-approval output.

FIG. 12 is a barrier-thickness tuning and target-band selection diagram illustrating different barrier layer-count conditions, corresponding resonant-energy placements, corresponding target wavelength bands, and a design-selection path.

### DETAILED DESCRIPTION

The present disclosure provides a zero-bias mid-infrared rectifier built around a vertical van der Waals resonant-tunnelling diode in which built-in electrode asymmetry and a quantized resonant sub-band cooperate to convert incident mid-infrared photons into DC electrical output without application of an external bias voltage. The core inventive mechanism is not generic photodetection, generic thermal sensing, or generic graphene transport. Rather, the core inventive mechanism is photon-assisted resonant tunnelling through a few-layer MoS2 barrier positioned between oppositely doped graphene electrodes such that illumination in a selected mid-infrared band produces net rectified current at zero bias. In preferred embodiments, the resonant condition is tuned to a target band near approximately 14 um, while in broader embodiments the same rectifying architecture may be tuned to other mid-infrared bands by adjusting barrier structure, resonant energy placement, or related design variables.

As used herein, “zero-bias” means that no externally applied rectifying bias is imposed across the active tunnelling structure during photon rectification. As used herein, “resonant sub-band” or “resonant level” means a quantized tunnelling state supported by the few-layer MoS2 barrier or quantum-well region. As used herein, “aligned” or “approximately aligned” means sufficiently close in energy that an incident photon-assisted transition places a carrier into or near the resonant tunnelling condition that produces rectified current. To provide objective boundaries, unless otherwise specified for a given embodiment: (i) “few-layer MoS2” means a MoS2 thickness from 1.0 nm to 3.0 nm and/or a layer count from 2 layers to 4 layers; (ii) “aligned” means an absolute difference between photon energy hnu and resonant energy E_res is less than or equal to the greater of (a) 5 percent of E_res and (b) 0.003 eV; and (iii) a “mid-infrared photon band” includes photon energies from 60 meV to 140 meV, corresponding to wavelengths from about 8.9 um to about 20.7 um. As used herein, “mid-infrared” includes the disclosed target band around approximately 14 um as well as related mid-infrared bands corresponding to resonant energies in the broader disclosed range. These definitions are provided to clarify the physical operation of the disclosed device family and are not intended to narrow the invention to only one exact wavelength, one exact barrier thickness, or one exact output format unless expressly recited.

As used herein, “built-in asymmetry” includes a Fermi-level offset, work-function difference, carrier-density difference, density-of-states imbalance, electrostatic gating condition, chemical doping condition, or combination thereof that causes photon-assisted resonant tunnelling in one direction to exceed the corresponding reverse process at zero applied bias. As used herein, “rectenna pixel” means a radiation-coupled unit in which a receiving structure delivers incident mid-infrared energy to the zero-bias resonant-tunnelling diode and the diode produces a rectified electrical output. These terms are intended to preserve both a stand-alone diode embodiment and antenna-coupled, arrayed, detector, harvesting, sensing, and verification-assisted embodiments.

In broad form, the disclosed device includes a first graphene electrode of a first doping type, a second graphene electrode of an opposite doping type, and a few-layer MoS2 quantum-well barrier disposed between the electrodes. The opposite doping types establish built-in asymmetry across the tunnelling structure. That built-in asymmetry positions and activates a resonant tunnelling condition in which incident mid-infrared photons having energy aligned to the resonant sub-band drive photon-assisted carrier transfer through the barrier and produce net DC current without external bias. In preferred embodiments, the first graphene electrode is p-doped, the second graphene electrode is n-doped, and the barrier is a three-layer MoS2 barrier that places the resonant sub-band near about 88 meV for operation near approximately 14 um.

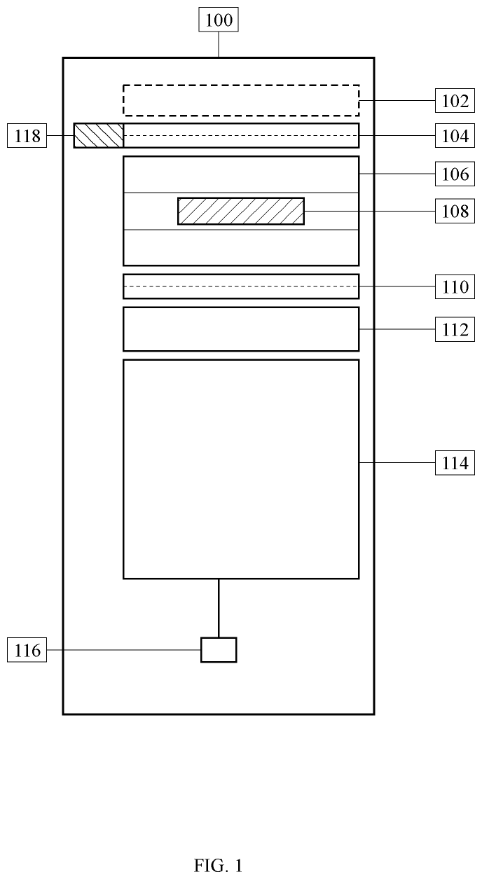

FIG. 1 depicts a cross-sectional device stack for a zero-bias resonant-tunnelling diode device 100 in which a first graphene electrode 104 and a second graphene electrode 110 are separated by a few-layer MoS2 barrier 106 containing a resonant sub-band region 108, supported on an oxide layer 112 and substrate 114, with optional encapsulation 102 and optional gate/contact features 116, 118. In the illustrated embodiment, the first graphene electrode 104 and the second graphene electrode 110 form opposed tunnelling electrodes, while the barrier 106 defines the tunnelling region through which photon-assisted resonant transport occurs. The barrier 106 may be configured as a few-layer MoS2 quantum-well barrier having a thickness selected to place the resonant sub-band region 108 at a target energy relative to the carrier populations in the electrodes.

The first graphene electrode 104 may be a monolayer graphene sheet or other graphene electrode layer of the first doping type. In preferred embodiments, the first graphene electrode 104 is p-doped and functions as an emitter-side electrode. The second graphene electrode 110 may likewise be a monolayer graphene sheet or other graphene electrode layer of opposite doping type. In preferred embodiments, the second graphene electrode 110 is n-doped and functions as a collector-side electrode. The use of opposite doping polarity is load-bearing because the disclosed zero-bias rectification depends on built-in asymmetry between the electrodes. Symmetric graphene junctions do not provide the disclosed zero-bias rectifying behavior.

The barrier 106 is preferably a few-layer MoS2 barrier positioned between the graphene electrodes and configured to support the resonant sub-band region 108. In preferred embodiments, the barrier 106 is a three-layer MoS2 barrier having a thickness of about 1.8 nm to about 2.0 nm and placing the resonant sub-band near about 88 meV. More broadly, the barrier 106 may be selected from a range of few-layer MoS2 thicknesses sufficient to position the resonant sub-band within a desired mid-infrared target band. The barrier thickness is therefore a direct tuning variable for resonant energy placement. A thinner barrier may shift the resonant condition upward in energy, while a thicker barrier may shift the resonant condition downward in energy.

In one preferred implementation, the first graphene electrode 104 is a CVD monolayer graphene sheet having approximately 95 percent coverage and is p-doped by about 15 minutes of HNO3 vapor exposure to produce a work-function shift of about +250 meV and a sheet resistance of about 200 ohms per square. In one preferred implementation, the second graphene electrode 110 is a CVD monolayer graphene sheet having approximately 95 percent coverage and is electrostatically gated through the substrate structure at about +7 V to provide a carrier density of about 4×10\hat{ }12 cm\hat{ }-2 and a sheet resistance of about 150 ohms per square. In a preferred embodiment, the resulting built-in asymmetry is about 87 meV and exceeds a 50 meV lower threshold. Graphene carrier transport may be characterized by a Fermi velocity of about 10\hat{ }6 m/s, giving a junction transit time on the order of 2 fs across an about 2 nm tunnelling region, which is well below the period of a 14 um photon. In a preferred three-layer embodiment, the MoS2 barrier 106 is an exfoliated 2H-MoS2 barrier having a thickness of about 1.9 nm, a bulk room-temperature bandgap of about 1.58 eV, a resonant level E0 of about 88 meV above the Fermi level, and tunnelling escape rates Gamma 1 and Gamma 2 each on the order of about 5 meV.

The oxide layer 112 and substrate 114 may provide mechanical support, dielectric isolation, and optional gate control. In one preferred implementation, the substrate 114 includes silicon and the oxide layer 112 includes a thermally grown silicon oxide layer. The optional gate/contact features 116, 118 may provide electrostatic tuning, electrical access, packaging access, or integration with additional structures such as antennas, readout electronics, output-conditioning circuitry, or array interconnects. The optional encapsulation 102 may protect the active tunnelling structure from contamination, environmental exposure, or moisture ingress. None of these support features alter the identity of the core invention, which remains the zero-bias asymmetric resonant-tunnelling diode defined by electrodes 104, 110 and barrier 106.

In operation, the device of FIG. 1 is configured so that the doping difference between the first graphene electrode 104 and the second graphene electrode 110 creates a built-in energy asymmetry across the barrier 106. That asymmetry positions the resonant sub-band region 108 such that incident photons in a selected mid-infrared band can promote carriers into a resonant tunnelling condition. Once the carrier energy is brought into alignment with the resonant sub-band region 108, the carrier tunnels through the barrier and is preferentially transferred because the electrode populations and/or density-of-states conditions on the two sides are asymmetric. The result is a net DC current even though no external bias is applied across the active diode stack.

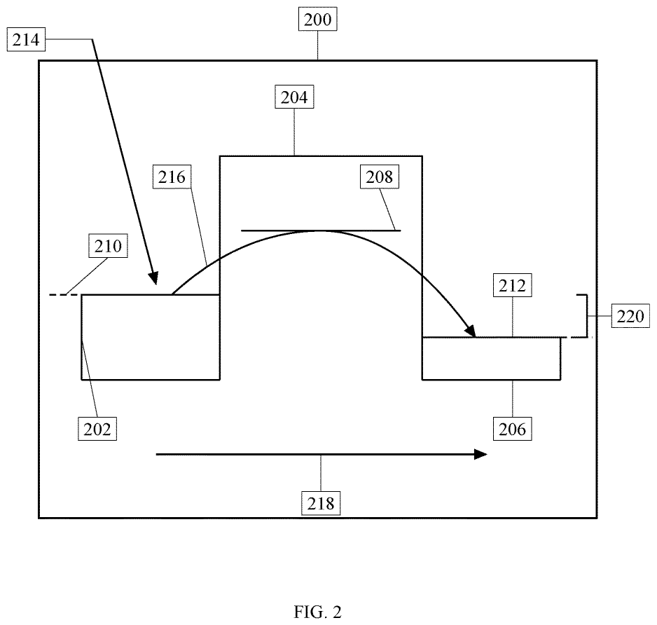

FIG. 2 depicts an energy-band and operating-state diagram 200 in which a built-in asymmetry 220 between first-side and second-side populations places a resonant level 208 in the barrier profile 204, such that an incident photon 214 excites a carrier to the resonant level and permits tunnelling along path 216 to produce net zero-bias current 218. More particularly, the first-electrode energy profile 202 and the second-electrode energy profile 206 are offset relative to one another by the built-in asymmetry 220, while the resonant level 208 is positioned within the barrier potential profile 204 so that photon-assisted tunnelling becomes energetically favorable under target-band illumination. The first-side Fermi level 210 and second-side Fermi level 212 illustrate that the two electrode sides are intentionally not equivalent.

The operating mechanism represented in FIG. 2 proceeds as follows. A mid-infrared photon 214 is incident on the device and is absorbed by a carrier associated with the first-electrode energy profile 202. Absorption of the photon raises the carrier energy into or near the resonant level 208. Once the carrier occupies or approaches that resonant condition, the barrier profile 204 permits resonant tunnelling along path 216 into the second-electrode energy profile 206. Because the first-side and second-side carrier populations are asymmetric, the transfer is not balanced by an equal reverse process under zero applied bias. Accordingly, a net rectified current 218 is generated. This is the physical basis for the disclosed zero-bias rectification.

The built-in asymmetry 220 is therefore not an incidental feature. It is required for the disclosed zero-bias rectifying function. The asymmetry may be produced by opposite doping polarity, different doping magnitudes, chemical functionalization of one electrode, electrostatic gating of one electrode, or combinations thereof, so long as the result is a non-zero built-in offset sufficient to activate the disclosed resonant zero-bias transport. In a preferred embodiment, the built-in asymmetry is about 87 meV. More broadly, the asymmetry may exceed a lower threshold sufficient to produce useful zero-bias rectification in the intended operating band.

The resonant level 208 is likewise a load-bearing feature rather than a generalized transport condition. The disclosed current mechanism is not merely direct conduction across a thin barrier and not merely thermal activation. Rather, the device is configured so that the barrier profile 204 supports a quantized resonant sub-band and the incident photon energy is selected or received in a range that drives carriers into that resonant state. In one preferred embodiment, the resonant level 208 is near about 88 meV, corresponding to approximately 14 um radiation. In other embodiments, the resonant level may be shifted by modifying barrier thickness or layer count to target a different mid-infrared band while preserving the same underlying zero-bias resonant-tunnelling architecture.

In some embodiments, the tunnelling current can be described by a resonant transmission relation of the form J(V)=(e/hbar) integral of T(E) times [f_p(E)−f_n(E)] dE, where T(E) follows a resonant transmission form centered on the resonant level 208 and f_p, f_n represent carrier occupation functions associated with the two electrode sides. At zero bias, the net current remains non-zero because the asymmetry between the first-side and second-side carrier populations causes the photon-assisted resonant condition to favor one net transport direction. This distinguishes the disclosed device from symmetric graphene structures, which do not provide the same zero-bias rectifying result.

In one example resonant model, the transmission term T(E) is approximated by a Breit-Wigner form T(E)=(Gamma1*Gamma2)/((E−E_res)\hat{ }2+(Gamma1+Gamma2)\hat{ }2/4), where E_res is the resonant sub-band energy and Gamma1 and Gamma2 are escape-rate linewidth terms associated with coupling to the respective graphene electrodes. In a preferred embodiment described herein, Gamma 1 and Gamma 2 are each on the order of about 5 meV, and the built-in asymmetry causes net current at zero applied bias because the effective carrier distributions and/or density-of-states on opposite sides are not identical at energies contributing to the photon-assisted resonant condition

In a preferred embodiment, the resonant condition shown in FIG. 2 is selected to correspond to approximately 14 um radiation and, in a further preferred doctrinal embodiment, is aligned to E_coh=phi\hat{ }-5. In that preferred doctrinal embodiment, E_coh=phi\hat{ }-5 is approximately 0.090 eV and corresponds to a wavelength lambda_coh=hc/E_coh of approximately 13.8 um, placing the preferred resonant condition at the upper edge of the 8 um to 14 um atmospheric window. In the preferred implementation, the resonant level E_res is about 88 meV, differing from E_coh by about 2 meV. Selected preferred relationships may be formally represented and machine-verified, including the absolute value of (E_res−E_coh), which is less than 0.003 eV, and the absolute value of (hnu_14 um−E_coh), which is less than 0.003 eV, and lambda_coh in the interval [13 um, 14.5 um]. In a further preferred framework, phi is fixed by x\hat{ }2=x+1, the exponent 5 in E_coh=phi\hat{ }-5 is treated as uniquely determined by the constraint 5=F5=2\hat{ }D−D with D=3, and eight-tick cancellation is represented by sum exp(2piik/8)=0. These preferred exact relations strengthen the 14 um embodiment, but the underlying physical make-and-use disclosure remains the asymmetric zero-bias resonant-tunnelling rectifier itself. In that preferred embodiment, the resonant-energy placement, wavelength correspondence, and associated design relations may be formally represented and machine-verified. However, the formal-verification layer remains supportive of the preferred embodiment and does not replace the underlying physical make-and-use disclosure of the diode itself. The physical invention remains the asymmetric zero-bias resonant-tunnelling rectifier represented by FIGS. 1 and 2.

In preferred proof-assisted embodiments, the formal representation may include data structures representing graphene electrode doping, Fermi shift, carrier density, MoS2 layer count, barrier thickness, resonant level, diode dynamic resistance, junction capacitance, antenna length, antenna impedance, rectenna-pixel performance, and array size. Machine-verified relationships may include resonance proximity between E_res and E_coh, proximity between a 14 um photon energy and E_coh, placement of lambda_coh in a target atmospheric-window interval, positivity of built-in asymmetry, positivity of cutoff frequency, coupling efficiency bounded by unity, unity coupling at exact impedance match, positivity of array output, and integer array-size witnesses. These proof-assisted relationships provide design-verification support for preferred embodiments and software-related claim families while remaining tethered to the disclosed physical diode and rectenna structures.

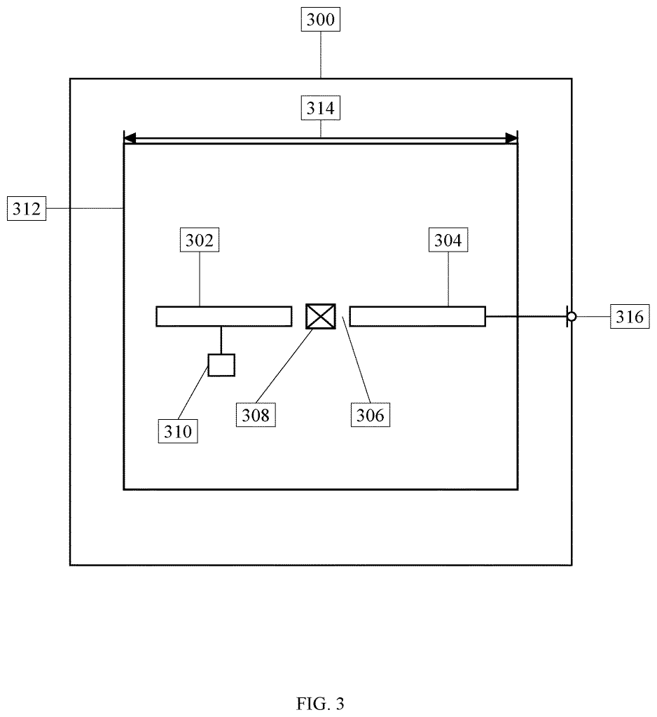

FIG. 3 depicts a rectenna pixel 300 in which antenna arms 302, 304 feed a central diode region 308 across feed gap 306, with optional contact pad 310 and pixel layout features 312, 314 providing a compact antenna-coupled rectifying unit. In the illustrated embodiment, the antenna arms 302, 304 form a dipole-type receiving structure configured to couple incident mid-infrared radiation into the diode region 308. The diode region 308 may contain the zero-bias resonant-tunnelling diode described with reference to FIGS. 1 and 2, such that photon energy collected by the antenna structure is delivered to the asymmetric graphene/MoS2/graphene tunnelling stack and converted into rectified DC output at current output node 316.

The rectenna pixel 300 provides a preferred implementation in which the core zero-bias diode is combined with an electromagnetic coupling structure sized for a selected target band. In one preferred embodiment, the antenna arms 302, 304 are dimensioned as a half-wave dipole for radiation near approximately 14 um, taking into account substrate dielectric effects and effective wavelength shortening relative to free space. In that preferred embodiment, the antenna geometry is selected to improve coupling of incident radiation into the diode region 308 and to reduce reflection losses between the antenna feed and the RF input presented by the resonant-tunnelling diode.

The feed gap 306 may define the electrical interface between the antenna arms 302, 304 and the diode region 308. In some embodiments, the diode region 308 is positioned directly within or immediately adjacent to the feed gap 306 so that high-frequency fields established by the antenna are concentrated across the active tunnelling region. This arrangement allows incident mid-infrared radiation to drive the photon-assisted resonant tunnelling condition described above while preserving the zero-bias operating architecture of the diode. Accordingly, the rectenna pixel 300 is not a distinct invention from the diode itself, but rather a preferred antenna-coupled embodiment of the same core rectifying mechanism.

The contact pad 310 may provide electrical access for measurement, output conditioning, packaging, array integration, or connection to downstream circuitry. The pixel boundary 312 and pixel pitch 314 illustrate that the rectenna pixel 300 may be repeated in a tiled arrangement to form larger arrays. In some embodiments, the pixel pitch 314 is selected to balance antenna footprint, interconnect spacing, and thermal or optical coupling considerations. In a preferred embodiment, the antenna structure and pixel spacing are selected to permit dense tiling without destroying the intended electromagnetic coupling characteristics of each individual pixel.

In one preferred antenna-coupled implementation, the antenna arms 302, 304 are metallic arms, such as gold arms, deposited and patterned on a substrate supporting the diode region 308. The antenna may be configured so that its effective impedance is near the dynamic input resistance of the zero-bias resonant-tunnelling diode. Impedance matching is important because improved matching increases the fraction of captured electromagnetic power delivered into the active diode region 308 rather than reflected at the antenna-to-diode interface. Thus, the antenna-coupled embodiment preserves the core zero-bias rectifier while adding a preferred electromagnetic front-end for improved capture efficiency.

In some embodiments, the antenna-coupled pixel 300 may further include optional reactive tuning structures, optional matching stubs, optional output buffers, or optional storage elements. Those features may be used to improve bandwidth, match, or downstream output handling, but they remain subordinate to the central architecture in which the diode region 308 itself performs zero-bias photon rectification. The broadest understanding of FIG. 3 should therefore remain focused on an antenna-coupled embodiment of the asymmetric resonant-tunnelling diode, not on any one particular output-conditioning circuit or one particular array format.

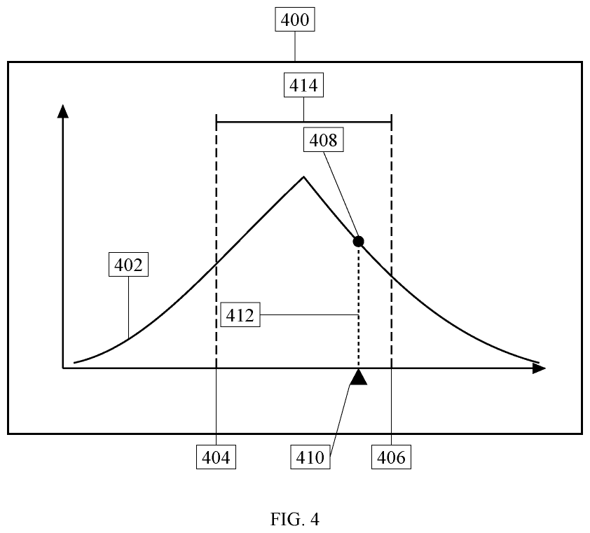

FIG. 4 depicts a spectral diagram 400 showing a thermal spectrum 402, the atmospheric window between bounds 404 and 406, and a preferred operating band 414 identified by resonance marker 408 and wavelength marker 410, optionally aligned with E_coh marker 412. In the illustrated embodiment, the thermal spectrum 402 represents radiation from a source of interest, while bounds 404 and 406 indicate a preferred atmospheric transmission window in which thermal radiation may propagate with relatively low absorption. The preferred operating band 414 is placed near the upper portion of that window and corresponds, in one preferred embodiment, to a resonant condition near approximately 14 um.

FIG. 4 supports the preferred design doctrine that the disclosed diode may be intentionally tuned to a target spectral band by selecting the resonant level of the tunnelling structure. In the preferred three-layer embodiment, resonance marker 408 corresponds to a resonant energy near about 88 meV, while wavelength marker 410 corresponds to approximately 14 um. By placing the resonant sub-band at that energy, the diode is configured to preferentially rectify photons in that preferred operating band 414. This spectral correspondence is not required to understand the broad invention, but it is an important preferred embodiment because it ties the resonant-tunnelling structure to a practical target band with strong utility for thermal radiation rectification.

The atmospheric window bounds 404 and 406 further illustrate that the preferred 14 um operating region lies in a portion of the spectrum that is practically useful for propagation and collection of thermal radiation. This provides a strategic engineering rationale for the preferred embodiment. The broad invention is a zero-bias asymmetric resonant mid-infrared rectifier; the preferred embodiment of FIG. 4 shows that the same architecture may be tuned to a target band having favorable environmental and thermal relevance.

In a further preferred doctrinal embodiment, the E_coh marker 412 represents a preferred coherence-energy correspondence in which the resonant condition is aligned to E_coh=phi\hat{ }-5. In that embodiment, the preferred 14 um resonant condition is presented not merely as an arbitrary design target, but as a preferred exact or near-exact alignment between a disclosed coherence energy and the spectral operating band of the device. Selected relationships associated with that preferred alignment, including resonance proximity, wavelength correspondence, and window placement, may be formally represented and machine-verified. However, the presence of marker 412 should not be taken to redefine the broad invention. Rather, FIG. 4 preserves a preferred, strategically stronger embodiment that may support narrower dependent claims, continuation claims, and proof-assisted design or verification claims.

The preferred operating band 414 may be selected in different ways depending on the embodiment. In some embodiments, the target band is selected first and the barrier thickness is then chosen to place the resonant level accordingly. In other embodiments, a preferred barrier structure, such as a three-layer MoS2 barrier, may determine the resonant condition and thereby define the preferred target band. In still other embodiments, a designer may use a target source temperature, target spectral environment, or target application class to select the desired spectral alignment. These selection paths all remain consistent with the same underlying architecture in which a resonant tunnelling condition is tuned to a desired mid-infrared band.

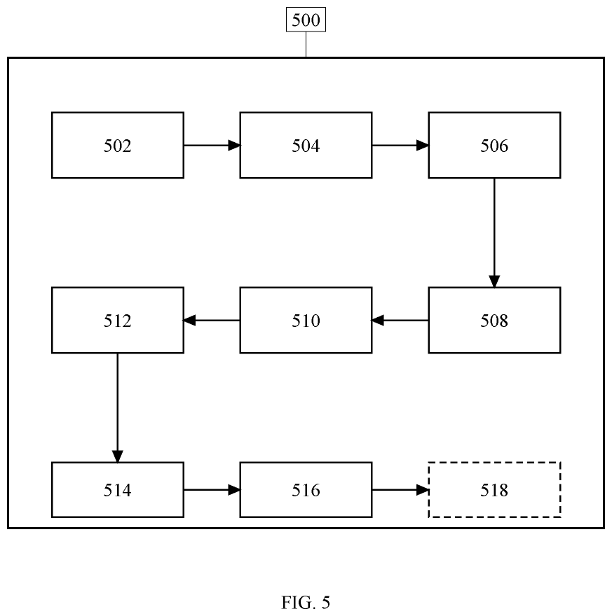

FIG. 5 depicts a fabrication workflow 500 including substrate preparation 502, first graphene transfer 504, barrier transfer 506, second graphene transfer 508, doping 510, antenna/contact patterning 512, encapsulation 514, packaging 516, and optional verification 518. The illustrated workflow provides one practical make-and-use route for forming the disclosed zero-bias resonant-tunnelling device and associated rectenna pixel structures. The order shown in FIG. 5 is exemplary and may be varied so long as the resulting structure preserves the asymmetric graphene/MoS2/graphene tunnelling architecture and the intended resonant operating condition.

At substrate preparation stage 502, a supporting substrate may be selected and cleaned. In one preferred embodiment, the substrate includes silicon and a dielectric layer, such as a thermally grown oxide layer, that supports transfer of the active device stack and optionally provides back-gate functionality. Cleaning, drying, baking, planarization, or similar substrate-preparation operations may be used to establish a suitable surface for subsequent transfer and fabrication steps.

At first graphene transfer stage 504, a first graphene electrode is placed on the prepared substrate. In preferred embodiments, the first graphene electrode is a monolayer graphene sheet transferred from a CVD growth source or other suitable source. Post-transfer treatment may include annealing, cleaning, residue removal, or surface conditioning. Where the first graphene electrode is intended to function as the collector-side or n-type electrode, the structure may subsequently be electrostatically biased or otherwise prepared for the intended doping polarity.

At barrier transfer stage 506, a few-layer MoS2 barrier is positioned over the first graphene electrode. In preferred embodiments, the barrier is identified as a three-layer MoS2 flake or film and is transferred so that it overlies the intended active diode region. Thickness verification may be performed before or after transfer, for example by optical contrast methods, AFM, or other thickness-sensitive techniques. The barrier-transfer stage is load-bearing because the barrier thickness directly affects placement of the resonant sub-band and therefore affects the target operating wavelength band of the finished device.

At second graphene transfer stage 508, a second graphene electrode is placed over the barrier to complete the vertical resonant-tunnelling stack. In preferred embodiments, the second graphene electrode is another monolayer graphene sheet aligned to overlap the barrier-covered active region. Orientation, overlap area, and transfer quality may be selected to reduce defects, maintain active-region coverage, and support the desired tunnelling geometry. The resulting stack, after stages 504, 506, and 508, forms the core active diode architecture of the disclosure.

At doping stage 510, one or both graphene electrodes are adjusted to establish opposite doping polarity and sufficient built-in asymmetry. In one preferred embodiment, one graphene electrode is chemically p-doped, for example by vapor exposure, while the opposite graphene electrode is electrostatically gated or otherwise configured as an n-type electrode. More broadly, the exact doping route may vary, provided that the resulting device has the built-in asymmetry required to support non-zero zero-bias rectification. Thus, stage 510 is functionally important even though the exact chemistry or field configuration may differ among embodiments.

In one preferred fabrication flow, substrate preparation stage 502 includes RCA-1 cleaning of a 90 nm SiO2/Si wafer, deionized-water rinse, and bake at about 120 C for about 10 minutes. At first graphene transfer stage 504, a CVD graphene sheet is transferred onto the substrate by a PDMS stamp and annealed at about 350 C in Ar/H2 for about 90 minutes to reduce residues, with Raman and AFM verification optionally used to confirm monolayer character and low roughness. At barrier transfer stage 506, a 3-layer MoS2 flake may be identified by optical contrast, verified at about 1.9+/−0.1 nm by AFM, and dry-stamped onto the first graphene electrode using a polycarbonate/PDMS transfer stack at about 60 C. At second graphene transfer stage 508, a second CVD graphene sheet may be transferred with an angular offset of about 30 degrees to suppress Moire superlattice formation and annealed at about 300 C in Ar/H2 for about 60 minutes. At antenna/contact patterning stage 512, PMMA resist may be spun to about 200 nm, the dipole and contact structures may be defined by e-beam lithography, and Ti/Au metal of about 2 nm/ 60 nm may be deposited and lifted off. At encapsulation stage 514, a SiN_x moisture barrier of about 20 nm may be deposited, and vias may be opened by reactive-ion etching. At packaging stage 516, backside vias, dicing, and optional flip-chip assembly may be used where desired.

In a more specific fabrication embodiment, the first graphene electrode may be transferred by a PDMS stamp onto a 90 nm SiO2/Si substrate and annealed at about 350 C in Ar/H2 for about 90 minutes. The MoS2 barrier may be a synthetic 2 H-MoS2 flake identified by optical contrast, verified by AFM to have a thickness of about 1.9+/−0.1 nm, and dry-stamped onto the first graphene electrode using a polycarbonate/PDMS transfer stack at about 60 C. The second graphene electrode may be transferred with an angular offset from about 25 degrees to about 35 degrees, preferably about 30 degrees, relative to the first graphene electrode to reduce or suppress Moire superlattice effects. The p-type electrode may be produced by about 15 minutes of HNO3 vapor exposure, and the n-type electrode may be produced by electrostatic gating through the silicon substrate at about +7 V. Metal antenna and contact structures may be formed by PMMA lithography, Ti/Au deposition of about 2 nm/60 nm, and lift-off. Encapsulation may include about 15 nm to about 30 nm of PECVD SiN_x, preferably about 20 nm, with contact vias opened by reactive-ion etching and optional tungsten backside vias used for flip-chip assembly.

At antenna/contact patterning stage 512, metallic contacts, antenna arms, feed structures, or related conductive features may be patterned and deposited. In a preferred embodiment, this stage forms the dipole antenna structure described with respect to FIG. 3 together with electrical access pads and feed connections to the active diode region. Lithographic patterning, metal deposition, and lift-off or etch-back processes may be used. This stage supports preferred rectenna embodiments but is not necessary to define the broadest diode embodiment.

At encapsulation stage 514, a protective coating or encapsulation layer may be formed over at least part of the structure. Encapsulation may improve environmental stability, reduce degradation, and support longer-term operation of the active stack. Openings or vias may be formed where external contacts are required. At packaging stage 516, the device may be integrated into a chip package, a carrier, a board, an imaging assembly, a sensing assembly, or an array structure, depending on the intended use.

Optional verification stage 518 may include structural, electrical, optical, and/or formal verification operations. Structural verification may include thickness measurement, spectral confirmation, and active-area inspection. Electrical verification may include dynamic resistance and capacitance measurements. Optical verification may include zero-bias photocurrent and responsivity measurements under target-band illumination. In preferred embodiments, the design selected by workflow 500 may also be evaluated in a proof-assisted framework that formally represents selected preferred relationships used by the disclosed embodiment. This optional verification stage strengthens the design and fabrication workflow without changing the underlying physical identity of the device being fabricated.

In preferred fabrication-acceptance embodiments, structural verification confirms monolayer graphene character, barrier thickness, active-region coverage, and contact integrity; electrical verification confirms zero-bias dynamic resistance, junction capacitance, and continuity of the antenna-to-diode feed; optical verification confirms zero-bias photocurrent or responsivity under target-band illumination; and design verification confirms that the selected resonant level, asymmetry, cutoff, and matching parameters fall within selected acceptance ranges. In one preferred acceptance set, the built-in asymmetry exceeds 50 meV, the resonant level is near about 88 meV, the junction capacitance is below 0.5 fF, the cutoff frequency is above the target operating frequency, and zero-bias responsivity at room temperature exceeds a selected threshold.

In a preferred design-acceptance procedure, a candidate diode or rectenna-pixel design is accepted for fabrication only if all of the following objective criteria are satisfied: (a) built-in asymmetry Delta_EF is at least 50 meV; (b) the resonant energy E_res is within the defined alignment tolerance of a target photon energy hnu for a selected target band; (c) a cutoff frequency computed as f_3 dB=1/(2pi R_d C_j) exceeds a target operating frequency for the selected target band; and (d) for antenna-coupled embodiments, a reflection coefficient magnitude at the antenna-to-diode interface is less than 0.15. In some embodiments, the procedure further includes predicting a zero-bias responsivity and accepting the candidate design only if the predicted or measured responsivity exceeds a specified threshold for the selected target band.

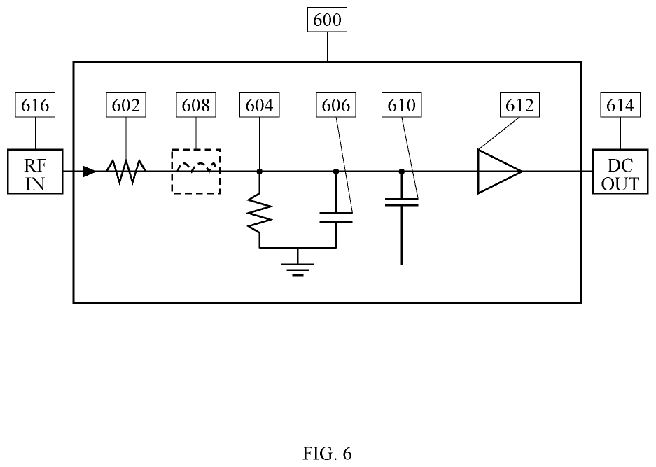

FIG. 6 depicts an equivalent circuit 600 in which an incident RF input 616 is coupled from antenna block 602 into diode resistance and capacitance blocks 604, 606, optionally through tuning element 608, and may charge storage capacitor 610 for buffered output through buffer stage 612 to DC node 614. The equivalent circuit 600 provides a preferred electrical representation of the antenna-coupled rectenna embodiment and illustrates how incident mid-infrared power is transferred into the active zero-bias resonant-tunnelling diode and then, in some embodiments, conditioned for downstream use. The antenna impedance block 602 represents the effective input presented by the electromagnetic receiving structure, while the diode resistance block 604 and diode capacitance block 606 represent, respectively, the dynamic input resistance and junction capacitance associated with the active resonant-tunnelling stack.

The equivalent circuit 600 supports the practical design doctrine that high-frequency optical or RF coupling into the diode is affected by the relationship between the impedance of the receiving structure and the dynamic input properties of the diode. In preferred embodiments, the antenna impedance block 602 is selected so that its effective impedance is near the resistance presented by block 604 at the target operating band. When the effective impedance match is improved, a greater portion of the captured mid-infrared power is delivered into the active diode rather than reflected at the interface. Thus, FIG. 6 shows a preferred electrical implementation of the same core rectifier already described with reference to FIGS. 1 through 3.

In one preferred antenna-coupled embodiment, the receiving structure is a gold half-wave dipole having a free-space target wavelength lambda 0 of about 14 um, an effective index n_eff of about sqrt(2.1) or about 1.45 at a SiO2/air interface, an effective wavelength lambda_eff of about 9.6 um, a dipole length of about 6 um including reactance tuning, and a dipole width of about 0.5 um. In preferred embodiments, acceptable antenna-coupled configurations include lithographic dipole lengths from about 4 um to about 8 um, operating frequencies from about 15 THz to about 30 THz, and coupling efficiencies of at least about 90 percent. A preferred source-truth design point uses Z_a of about 32 ohms and R_d of about 41 ohms, giving a reflection coefficient of about 0.123 and coupling efficiency of about 0.985 before engineering allowance. In verification-assisted embodiments, impedance matching may also be evaluated by a ratio-cost expression J(r)=0.5×(r+1/r)−1, where r=R_d/Z_a, and values near zero indicate near-matched antenna-to-diode coupling. In a preferred implementation, the antenna impedance Z_a is about 32 ohms and the diode RF input resistance R_d is about 41 ohms. The resulting reflection coefficient Gamma=(41−32)/(41+32) is about 0.123, corresponding to a coupling efficiency eta=1−Gamma\hat{ }2 of about 0.985, or about 96 percent after engineering allowance. In a further preferred matching analysis, J(R_d/Z_a)=J(41/32)=J(1.28)=0.5×(1.28+1/1.28)−1 is about 0.031, which is close to the matching minimum J=0. Selected preferred matching relations may also be formally represented and machine-verified, including eta less than or equal to 1 and the unity condition at exact match.

The diode resistance block 604 corresponds to the small-signal RF input resistance of the active zero-bias resonant-tunnelling diode, while the diode capacitance block 606 corresponds to the effective junction capacitance of the active tunnelling region. The combination of these quantities affects the effective cutoff performance of the device. In preferred embodiments, the capacitance is sufficiently small and the resistance is sufficiently controlled that the resulting cutoff frequency remains above the intended operating band. This is significant because the disclosed device is intended to rectify radiation in a regime that is difficult to reach with more conventional diode structures. Accordingly, the equivalent circuit 600 provides a design-facing representation of how the physical tunnelling structure translates into high-frequency rectifying behavior.

In one preferred device implementation, the small-signal RF input resistance R_d is about 41 ohms at zero bias and the junction capacitance C_j is about 0.16 fF, giving a 3 dB cutoff frequency f_3 dB=1/(2pi R_d C_j) of about 24 THz by conservative estimate, with detailed modeling indicating that f_3 dB may exceed 34 THz when parasitic effects are more fully resolved. In a demonstrated preferred operating point, zero-bias responsivity R0 is about 8.9 A/W at 300 K under 14 um CW illumination. Under a preferred 600 K blackbody source condition with an effective mid-IR flux of about 3.4×10\hat{ }4 W/m\hat{ }2 and an effective illuminated aperture of about 25 um\hat{ }2, captured optical power P_capt is about 0.84 uW, short-circuit current I_sc is about 7.4 uA, buffered DC output is about 80 mV average, and buffered electrical output power is about 0.60 uW average per pixel. The RF resistance and capacitance values correspond to the high-frequency antenna-facing port, whereas the buffered output values correspond to charge accumulated and delivered through downstream circuitry and should not be confused with an instantaneous diode-terminal DC operating point.

The optional tuning element 608 may represent a reactive stub, matching structure, compensation element, or other impedance-adjustment feature that improves coupling between antenna block 602 and the active diode. In some embodiments, tuning element 608 is omitted. In other embodiments, tuning element 608 is selected to reduce residual mismatch or to broaden useful coupling over a target band. Because the disclosed invention fundamentally resides in the zero-bias rectifying diode itself, tuning element 608 remains an optional preferred feature rather than a required limitation of the broadest embodiments.

Storage capacitor 610, buffer stage 612, and DC output node 614 illustrate optional output-conditioning structures that may be used after rectification has already occurred. These elements are important because the RF input behavior of the diode and the downstream buffered-output behavior need not be identical. In some embodiments, the active resonant-tunnelling diode presents the high-frequency input represented by blocks 604 and 606, while the recovered DC energy is accumulated on storage capacitor 610 and delivered through buffer stage 612 to output node 614 in a more usable form. Thus, FIG. 6 clarifies that the broad invention is the rectifying mechanism itself, whereas output buffering, accumulation, and conditioning are downstream electrical embodiments built on that mechanism.

In narrower preferred embodiments, the output-conditioning path shown in FIG. 6 may be expanded to include charge pumps, regulators, level shifters, switched-capacitor accumulators, sample-and-hold structures, detector-interface circuits, or sensor-support circuits. These additions may be useful in harvesting, imaging, or sensing implementations. However, they remain subordinate to the primary architecture in which incident mid-infrared radiation is first converted to DC electrical current by the asymmetric resonant-tunnelling diode. The specification should therefore maintain the distinction between the core rectifier and the optional downstream output circuitry represented in FIG. 6.

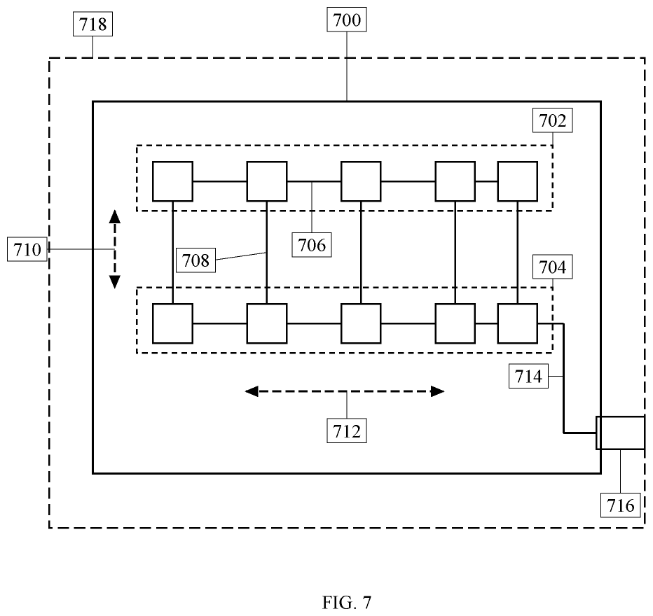

FIG. 7 depicts a tiled array 700 of rectenna pixels arranged on footprint 718, with interconnect paths 706, 708 and example series/parallel aggregation paths 710, 712 feeding an output bus 714 and optional regulated output interface 716. The array 700 may include a plurality of the rectenna pixels described with reference to FIG. 3, each pixel including an antenna-coupled or otherwise radiation-coupled zero-bias resonant-tunnelling diode. The array architecture provides a preferred route for scaling the disclosed rectification mechanism from a single diode or single pixel to a larger harvesting, sensing, or imaging structure.

The first pixel group 702 and second pixel group 704 illustrate that the array 700 may be organized into repeated units, tiles, subarrays, or addressable zones. Row interconnects 706 and column interconnects 708 may be used in matrix-addressed, imaging, sensing, or tiled-output formats. In other embodiments, groups of pixels may be deliberately interconnected in series along grouping path 710, in parallel along grouping path 712, or in mixed series-parallel architectures depending on desired output voltage, current, impedance, readout mode, or system-level integration strategy. As such, FIG. 7 supports not only simple tiling but also a family of array-level electrical architectures.

The array output bus 714 may collect power or signals from a plurality of pixels and deliver the aggregated output to regulated output interface 716. In some embodiments, output interface 716 may include regulation, buffering, multiplexing, detector readout, charge accumulation, or other downstream electrical processing. In harvesting embodiments, the bus 714 may be used to collect aggregate DC power from many pixels. In sensing or imaging embodiments, the bus 714 may instead support signal extraction, addressing, timing, or pixel-by-pixel readout. Accordingly, FIG. 7 preserves a broad family of array-level uses while keeping the device-level rectification mechanism fixed.

The footprint 718 illustrates that the array may be formed on a common substrate or chip area and may occupy only a portion of a larger wafer, die, carrier, or package. In preferred embodiments, pixel pitch, antenna dimensions, and interconnect spacing are selected to permit dense tiling while maintaining useful electromagnetic coupling and manageable interconnect routing. The array 700 may therefore be adapted for waste-heat harvesting, compact power scavenging, imaging, wavelength-selective sensing, or related functions. However, those downstream uses do not redefine the array. The array remains a plurality of pixels built from the same zero-bias resonant-tunnelling rectifier kernel.

In some embodiments, series grouping path 710 is used where a higher aggregated voltage is preferred, while parallel grouping path 712 is used where a higher aggregated current is preferred. In one preferred array embodiment, a 512×512 array includes 262,144 rectenna pixels on a common silicon substrate or wafer-scale carrier. Using a preferred modeled buffered output of about 0.60 uW per pixel, the array provides about 157 mW, or about 160 mW, of continuous DC output under the stated 600 K source condition. One practical aggregation arrangement may include series-connected groups for voltage buildup and parallel-connected groups for current buildup, such as a 128-series by 2048-parallel arrangement, while other series-parallel groupings may be selected to match downstream voltage, current, impedance, regulation, or packaging requirements. Mixed architectures may also be used to balance bus voltage, current handling, signal-to-noise ratio, power conditioning, or readout compatibility. The specification should preserve these interconnect architectures as optional array-level embodiments and fallback claim lanes, but should avoid implying that any one particular series/parallel topology is required for practice of the core invention.

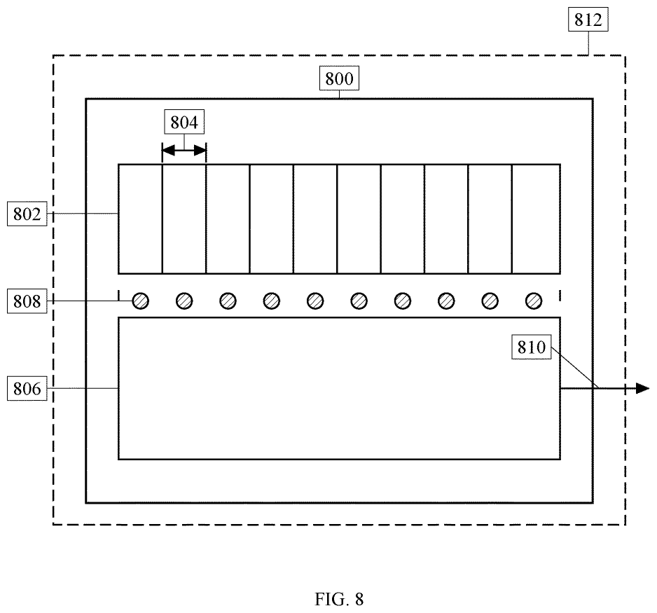

FIG. 8 depicts a focal-plane-array implementation 800 in which a pixel array region 802 having pitch 804 is integrated with a ROIC layer 806 through bonding interface 808 and read out along readout path 810 within package boundary 812. FIG. 8 illustrates a downstream detector embodiment in which a plurality of disclosed rectifying pixels are arranged as an imaging or detector plane and coupled to readout integrated circuitry. In this embodiment, each pixel in region 802 may include the zero-bias resonant-tunnelling architecture described above, optionally with antenna coupling or other local structures adapted to the intended spectral band.

The pixel pitch marker 804 indicates that the focal-plane-array embodiment may be designed at a selected detector pitch suitable for imaging or spatially resolved sensing. The readout integrated circuitry layer 806 may include timing logic, multiplexing, addressing, storage, amplification, conversion, correction, or related signal-handling functions. The bonding interface 808 may include bump-bonding, flip-chip integration, conductive interposers, or other coupling structures by which the rectifying pixel array region 802 is electrically connected to the ROIC layer 806. Readout path 810 represents the extraction of pixel or array data for imaging, sensing, or downstream processing.

FIG. 8 is significant because it demonstrates that the disclosed zero-bias resonant rectifier can be embodied not only as a power-harvesting element but also as a detector element in a spatially resolved array. In this embodiment, rectified current or voltage from each pixel may be sampled, buffered, integrated, or otherwise processed by circuitry associated with the ROIC layer 806. The detector implementation may therefore use the same core asymmetric resonant-tunnelling mechanism while changing the downstream function from aggregate power extraction to signal acquisition or image formation. This supports system-level flexibility without changing the identity of the core invention.

In one downstream detector embodiment, a focal-plane-array implementation may include a 640×480 pixel format with a pixel pitch on the order of about 12 um and readout through a CMOS ROIC using flip-chip or related bonding. In a modeled detector embodiment, the focal-plane-array implementation may operate uncooled at about 300 K, with detector performance estimated from the zero-bias responsivity and readout parameters of the rectifying pixels. Example detector-oriented figures of merit may include noise-equivalent power on the order of about 1 pW per square-root hertz, detectivity on the order of about 3×10\hat{ }9 cm square-root hertz per watt, and frame-rate capability above 60 frames per second where the readout circuitry rather than the resonant-tunnelling diode limits frame rate. These detector-oriented values are provided as modeled downstream system examples and do not redefine the core diode structure. In a preferred modeled detector point, responsivity remains about 8.9 A/W at 14 um, with detector-oriented figures of merit such as noise-equivalent power, detectivity, and frame-rate capability estimated from the diode and readout parameters. These detector-oriented values should be understood as downstream system embodiments built on the disclosed rectifying pixel architecture rather than as the core invention itself.

In some embodiments, the focal-plane-array implementation 800 may be configured for passive thermal imaging, wavelength-selective imaging, target detection, environmental monitoring, gas sensing, or other mid-infrared detector functions. In such embodiments, the pixel architecture may remain substantially the same while the readout architecture, packaging, signal processing, and calibration procedures are adapted to the intended detector use. Thus, FIG. 8 should be understood as a downstream detector/readout embodiment that preserves continuation support for imaging-oriented claims while remaining subordinate to the central zero-bias resonant-tunnelling diode architecture disclosed herein.

In narrower embodiments, the detector-plane implementation may include wavelength-grouped subarrays, local buffering, integration capacitors, synchronized sampling, per-pixel amplification, or calibration features. Those details may be included to support focused imaging or detector claim sets, but they are not required to understand the underlying invention. The broad significance of FIG. 8 is that disclosed rectifying pixels can be arrayed and electrically interfaced to a readout circuit for detector use, thereby extending the same core diode mechanism into a focal-plane-array environment.

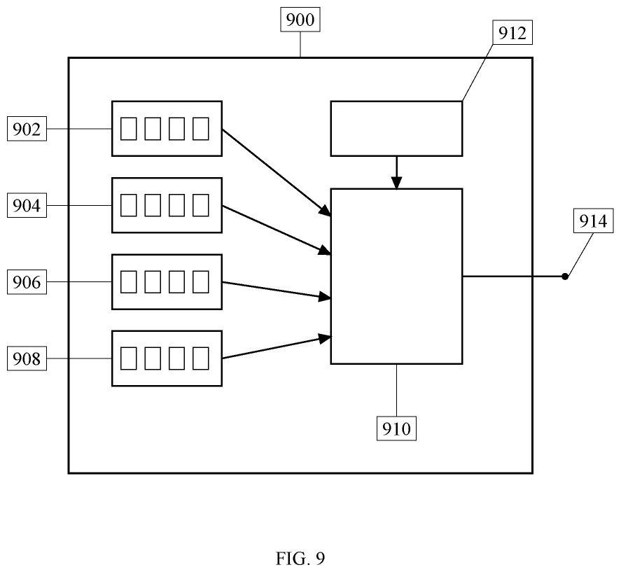

FIG. 9 depicts a gas-sensing system 900 including a reference pixel group 902, one or more gas-band groups 904, 906, 908, a ratio-processing block 910, optional power-conditioning block 912, and gas-concentration output 914. In this downstream embodiment, the core zero-bias resonant-tunnelling rectifier is adapted into a multi-band sensing architecture in which different pixel groups are tuned to different target wavelength bands. The reference pixel group 902 may be tuned to a reference band in or near a transmission window, while one or more gas-band groups 904, 906, 908 may be tuned to absorption bands associated with one or more target species.

In one embodiment, the reference pixel group 902 is tuned to a wavelength near approximately 14 um or another selected reference wavelength, while gas-band groups 904, 906, 908 are tuned to one or more bands associated with carbon dioxide, water vapor, ozone, methane, or other gases of interest. In a representative self-powered gas-sensing embodiment, a first pixel group may be tuned near 14.0 um as a reference group in or near an atmospheric-window band, a second pixel group may be tuned near 14.7 um for carbon dioxide absorption, a third pixel group may be tuned near 12.0 um for water-vapor absorption, and a fourth pixel group may be tuned near 10.6 um for ozone absorption. A methane-sensing embodiment may use a modified antenna and barrier-selection condition for a methane absorption band such as about 7.7 um. Ratio-processing block 910 may compute a ratio between a gas-band pixel output and a reference pixel output, such as a carbon-dioxide band output divided by a 14.0 um reference output, to reduce common-mode source or collection variation. Incident radiation received by the different pixel groups generates corresponding rectified outputs, and the relative magnitudes of those outputs may be processed by ratio-processing block 910 to estimate concentration, presence, absence, spectral contrast, or another target sensing metric. Thus, the gas-sensing architecture of FIG. 9 uses the same underlying rectifying pixel concept while extending it into a wavelength-discriminating sensor format.

The ratio-processing block 910 may compare outputs from the reference pixel group 902 and one or more gas-band groups 904, 906, 908 to form normalized signals that are less sensitive to source intensity variation, common-mode drift, environmental fluctuation, or collection geometry. In some embodiments, the ratio-processing block 910 may perform analog comparison, digital comparison, table lookup, calibration correction, thresholding, pattern recognition, or concentration estimation. In other embodiments, the output from one group may simply be compared to the output from another group to indicate whether a selected absorption feature is present. The broad significance of FIG. 9 is that the disclosed zero-bias rectifier may be deployed in multiple tuned channels and used for comparative spectral sensing.

Optional power-conditioning block 912 illustrates that one portion of the pixel array may be used to support powering, buffering, or self-powered operation of the sensing architecture. In some embodiments, a reference or harvesting band may provide sufficient rectified output to power ratio-processing logic, control circuitry, storage elements, telemetry, wake-up functions, or related downstream electronics. In other embodiments, block 912 may simply buffer or regulate outputs from the sensing pixels for easier use by external circuitry. Accordingly, FIG. 9 preserves support for self-powered gas-sensing embodiments without making self-powering a required aspect of every sensing implementation.

Gas-concentration output 914 may represent a direct concentration estimate, a threshold-crossing indication, a gas-presence flag, a spectral signature, or another derived output from the system 900. In preferred downstream embodiments, output 914 may be provided to local electronics, remote telemetry, industrial monitoring systems, environmental monitors, building-control systems, or similar applications. These uses remain downstream from the core invention. The essential point is that the same asymmetric resonant-tunnelling diode architecture may be arranged into wavelength-selective groups to provide a useful mid-infrared sensing platform.

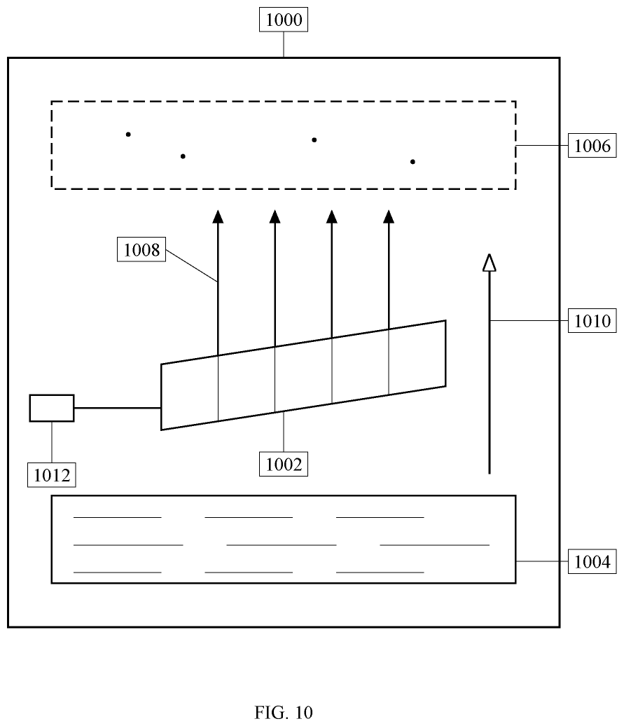

FIG. 10 depicts a sky-facing thermoradiative system 1000 in which array 1002 exchanges radiation between a warm-side environment 1004 and a cold-sky environment 1006 along path 1008 to create a net flux 1010 delivered through output interface 1012. FIG. 10 illustrates a prophetic downstream embodiment in which the disclosed rectifying array is oriented so that a warm device environment radiatively exchanges energy with a colder effective sky environment. In such an embodiment, the rectifying structure is used to convert a radiative flux imbalance into usable electrical output.

The sky-facing array 1002 may include a tiled plurality of rectifying pixels of the type described above. Warm-side environment 1004 may correspond to an ambient terrestrial environment, device temperature, or other relatively warmer radiative source. Cold-sky environment 1006 may correspond to an effective sky-facing sink in a relevant atmospheric transmission band. Emitted photon path 1008 and net flux direction 1010 represent the concept that a net radiative exchange condition may be presented to the rectifying pixels, allowing the array to develop a useful output through the same zero-bias resonant-tunnelling mechanism described elsewhere in this specification.

FIG. 10 should be understood as a prophetic or future-oriented system embodiment rather than as a redefinition of the device core. In one prophetic thermoradiative embodiment, the sky-facing array may include about 1024×1024 pixels arranged over an area on the order of about 16 mm by about 16 mm. The warm-side environment may be at about 300 K, while the cold-sky environment may provide a lower effective radiative temperature in an atmospheric-window band. A practical thermoradiative power level may be estimated on the order of about 5 W/m\hat{ }2 under selected atmospheric and emissivity assumptions, corresponding to about 1.3 mW from a 2.56 cm\hat{ }2 array area. These values are prophetic system-level examples and are not required for practice of the zero-bias resonant-tunnelling diode itself. The central invention remains the zero-bias asymmetric resonant rectifier. The thermoradiative embodiment simply places that rectifier into an environmental geometry in which a net radiative imbalance may be harvested. In some embodiments, output interface 1012 may provide buffered, conditioned, stored, or regulated power for downstream electronics, sensing nodes, communication modules, or supplemental low-power operation. In other embodiments, interface 1012 may simply expose the raw or partially conditioned array output.

In some embodiments, optical filtering, angular selection, thermal isolation, directional mounting, weather-resistant encapsulation, or other system-level enhancements may be used to improve the performance of the thermoradiative configuration. Such features may be useful in a specific product implementation, but they remain optional and downstream. The value of FIG. 10 is that it preserves a continuation-ready disclosure path for radiative-harvesting systems based on the disclosed rectifying architecture while keeping that architecture itself identifiable and defensible.

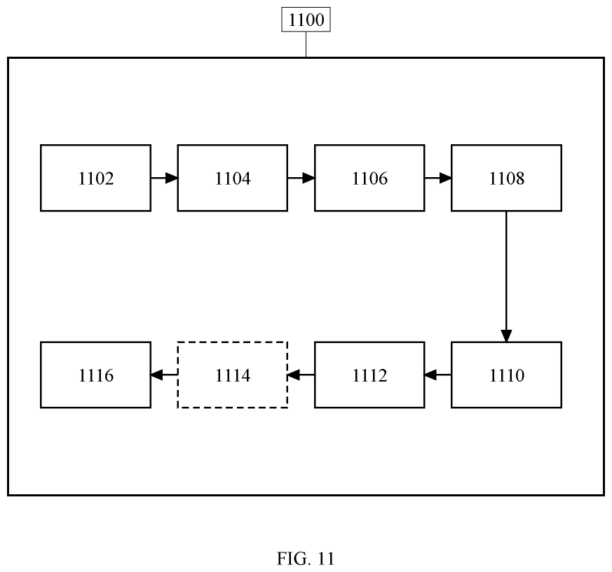

FIG. 11 depicts a design workflow 1100 in which a target-band input 1102 is used to select barrier parameters in block 1104, evaluate asymmetry 1106, bandwidth 1108, and matching 1110, estimate performance in block 1112, optionally machine-verify selected relationships in block 1114, and issue a design-approval output 1116. FIG. 11 supports a verification-assisted design embodiment in which the physical device architecture described herein is selected, tuned, and validated through a structured design process. This figure is important because it preserves support for software, workflow, CRM, and design-verification claim families while remaining tethered to the actual diode architecture.

At target-band input 1102, a designer, system, or software workflow may receive a target wavelength, target photon energy, target source temperature, target detector band, target application class, or other operating requirement. Based on that input, barrier-selection block 1104 may select a barrier layer count, barrier thickness, target resonant level, or related structural configuration intended to place the resonant sub-band within the desired operating band. In one preferred pathway, block 1104 selects a three-layer MoS2 barrier to place the resonant condition near about 88 meV for approximately 14 um operation. In alternative pathways, block 1104 may select a different layer count or thickness to target a different band.

Asymmetry-evaluation block 1106 may determine whether the selected electrode doping polarity and magnitude are sufficient to establish a built-in asymmetry that supports non-zero zero-bias rectification. In some embodiments, block 1106 may compute a target Delta_EF value, confirm that opposite doping is present, compare the result against a threshold, or determine whether a selected chemical and/or electrostatic doping arrangement is expected to place the resonant sub-band into a usable transport condition. This block preserves the design doctrine that the disclosed rectifier depends on intentional electrode asymmetry rather than merely on thin-barrier conduction.

Bandwidth-evaluation block 1108 may compute, estimate, or verify dynamic resistance, junction capacitance, and effective cutoff behavior. In preferred embodiments, block 1108 may confirm that the selected diode configuration provides sufficient high-frequency response in the intended operating band. Matching-evaluation block 1110 may compute or verify the relationship between antenna impedance and diode input resistance for antenna-coupled embodiments. In some embodiments, block 1110 may also evaluate tuning structures, reflection coefficients, coupling efficiency, or related match metrics. These stages help ensure that the physical structure selected at block 1104 is not only spectrally aligned but also practically operable as a diode or rectenna.

Performance-estimation block 1112 may compute, estimate, or simulate responsivity, short-circuit current, buffered voltage, per-pixel output power, array output, detector response, or other outputs for one or more candidate embodiments. This block may use analytical models, empirical inputs, calibration data, lookup tables, simulation routines, measured device parameters, or combinations thereof. In some embodiments, block 1112 may issue performance predictions for a single diode, a rectenna pixel, a tiled array, an imaging plane, or a sensing system. Thus, FIG. 11 preserves support for output prediction and design selection workflows without implying that all such estimates are necessarily measured.

Formal-verification block 1114 may, in selected preferred embodiments, formally represent one or more selected design relationships in a proof system and optionally machine-verify whether those relationships hold for a given candidate design. Examples include resonance proximity to a preferred target energy, wavelength correspondence, asymmetry positivity, impedance-matching bounds, and array-size or output witnesses. The use of block 1114 does not mean that formal proof alone establishes empirical performance. Rather, block 1114 provides a structured verification layer for selected preferred relationships used in design selection and claim support. This distinction should remain clear in the specification.

Design-approval output 1116 may indicate that a candidate structure satisfies the selected design criteria for fabrication, further simulation, deployment, or claim support. The design workflow may be implemented as stored instructions on a non-transitory computer-readable medium. In such embodiments, the instructions may compute a barrier layer count or barrier thickness for a target photon energy, compute or estimate antenna length for impedance matching, evaluate built-in asymmetry, evaluate dynamic resistance and junction capacitance, compute an estimated cutoff frequency, compute a coupling-efficiency or impedance-ratio metric, simulate or estimate photon-assisted resonant tunnelling current, predict pixel or array output for a source temperature and pixel count, and generate a fabrication-ready parameter set or verification report. In proof-assisted embodiments, the instructions may further cause a formal proof system to represent and verify selected relationships including resonance proximity, wavelength correspondence, asymmetry positivity, impedance-matching bounds, and array-size or output witnesses. In some embodiments, output 1116 may be a pass/fail output, a ranked output, a parameter set, a fabrication-ready configuration, a verification certificate, a design report, or another design artifact. The workflow of FIG. 11 therefore preserves a useful bridge between the physical diode invention and a computer-assisted design/verification family of embodiments. Such embodiments are subordinate to the core rectifying diode, but they are strategically important for preserving broader application and software-related claim support.

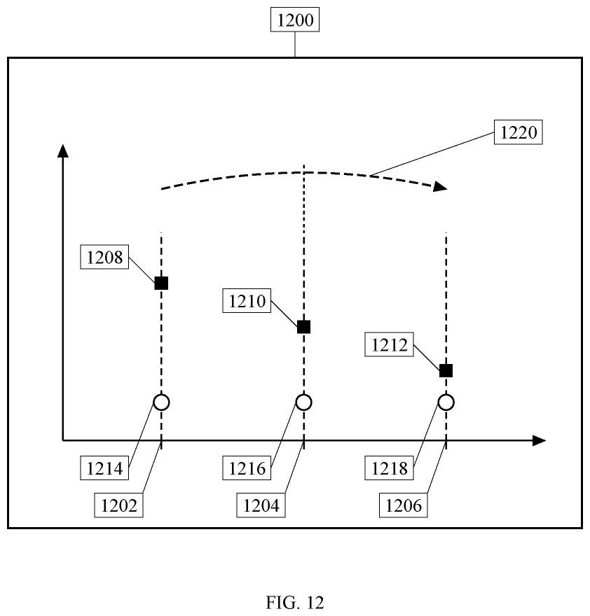

FIG. 12 depicts a tuning diagram 1200 showing different barrier layer-count conditions 1202, 1204, 1206, corresponding resonant-energy markers 1208, 1210, 1212, corresponding target-band markers 1214, 1216, 1218, and a design-selection path 1220 for selecting a target resonant condition. FIG. 12 illustrates that the disclosed zero-bias resonant-tunnelling architecture is not limited to only one exact barrier thickness, even though the three-layer embodiment is the strongest preferred embodiment. Instead, the barrier layer count may be used as a structural tuning variable that positions the resonant sub-band at different energies and thereby targets different mid-infrared wavelength bands while preserving the same underlying asymmetric graphene/MoS2/graphene rectifying mechanism.

In the illustrated embodiment, first layer-count condition 1202 corresponds to a thinner barrier configuration, second layer-count condition 1204 corresponds to a preferred intermediate barrier configuration, and third layer-count condition 1206 corresponds to a thicker barrier configuration. The corresponding resonant-energy markers 1208, 1210, 1212 indicate that different barrier thicknesses shift the resonant tunnelling condition to different energies. In one preferred implementation, second layer-count condition 1204 corresponds to a three-layer MoS2 barrier that places the resonant sub-band near about 88 meV, represented by second resonant-energy marker 1210, and thus targets approximately 14 um radiation, represented by second target-band marker 1216.

First layer-count condition 1202 may correspond, for example, to a two-layer MoS2 barrier, which shifts the resonant condition upward in energy toward about 140 meV, represented by first resonant-energy marker 1208, and correspondingly shifts the target wavelength band downward toward a shorter wavelength band, represented by first target-band marker 1214. Third layer-count condition 1206 may correspond, for example, to a four-layer MoS2 barrier, which shifts the resonant condition downward in energy toward about 60 meV, represented by third resonant-energy marker 1212, and correspondingly shifts the target wavelength upward toward a longer wavelength band, represented by third target-band marker 1218. These disclosed examples demonstrate that barrier thickness is a direct structural tuning parameter for resonant-energy placement.

Design-selection path 1220 illustrates that a target operating band may be used to select an appropriate layer-count condition and thus an appropriate resonant-energy placement. In some embodiments, the design process begins with a target source spectrum, target application, target wavelength, or target photon energy, and then selects a barrier thickness that positions the resonant level accordingly. In other embodiments, a preferred barrier architecture is selected first and the corresponding operating band is then adopted as the intended use band. In either direction, FIG. 12 preserves the doctrine that layer count and barrier thickness are not incidental dimensions but are load-bearing structural controls that set the resonant operating condition of the rectifier.

In a preferred embodiment, the intermediate layer-count condition 1204 is selected because it places the resonant condition near approximately 14 um and, in a further preferred doctrinal embodiment, near E_coh=phi\hat{ }-5. However, the broader invention is not limited to only that exact resonant target. Rather, the invention includes a family of zero-bias asymmetric resonant-tunnelling rectifiers in which the barrier is structurally selected to place the resonant sub-band in a desired mid-infrared operating band. This is important for claim strategy because it supports both a broad independent claim directed to the rectifying architecture and narrower fallback claims directed to specific layer counts and target bands.

In a further preferred doctrinal embodiment, the preferred three-layer resonant condition places E_res near E_coh=phi\hat{ }-5 such that each preferred rectified photon carries approximately one coherence quantum of energy. In that embodiment, rectified output may be processed through a phi-ratio switched-capacitor accumulator having a least significant energy increment set to E_coh, with energy released in integer multiples n x E_coh so as to preserve a preferred ledger-neutral extraction doctrine over an eight-tick cycle. In a still further preferred embodiment, rectification events are synchronized to an eight-tick cadence represented by sum exp(2piik/8)=0. Selected preferred relations associated with resonance proximity to E_coh and preferred 14 um photon correspondence may be formally represented and machine-verified. This doctrinal embodiment is narrower than the broad diode architecture, but it should be preserved in the specification because it provides a strategically strong fallback family for continuation and dependent-claim practice.

The following examples are provided to illustrate representative embodiments, design selections, operating conditions, and downstream uses of the disclosed technology. Unless expressly stated otherwise, the examples are not intended to limit the scope of the disclosure. Certain examples correspond to demonstrated material, certain examples correspond to preferred modeled embodiments, and certain examples correspond to prophetic or future-oriented embodiments. This distinction is preserved so that measured results, modeled outputs, and prospective system-level implementations are not conflated.

A preferred diode embodiment includes a first graphene electrode of a first doping type, a three-layer MoS2 barrier having a thickness of about 1.9 nm, and a second graphene electrode of an opposite doping type arranged in a vertical van der Waals resonant-tunnelling stack. In a preferred implementation, the first graphene electrode is p-doped and the second graphene electrode is n-doped. The resulting built-in asymmetry is about 87 meV, and the resonant sub-band is positioned near about 88 meV. The three-layer barrier is selected because it places the resonant condition in a preferred band near approximately 14 um. Barrier thickness in this preferred embodiment may be verified by AFM.

This example is important because it represents the strongest load-bearing embodiment of the disclosure. It ties together the physical stack, the preferred barrier thickness, the preferred polarity arrangement, the preferred resonant-energy placement, and the preferred target band. In a further preferred doctrinal embodiment, the approximately 88 meV resonant condition is aligned to E_coh=phi\hat{ }-5 and the corresponding wavelength lies near approximately 13.8 um to 14 um. Selected relationships used by this preferred embodiment may be formally represented and machine-verified.

The preferred diode embodiment of Example 1 is illuminated under approximately 14 um CW radiation at room temperature. Under those conditions, photon-assisted resonant tunnelling occurs through the quantized resonant sub-band without the application of an external rectifying bias. In a demonstrated implementation described in the disclosure, the device exhibits measured zero-bias responsivity of about 8.9 A/W at 300 K under 14 um CW illumination.

This example demonstrates that the disclosed structure is not merely a conceptual or theoretical tunnelling device, but a practical zero-bias rectifier in the preferred operating band. The example also supports narrower claim positions directed to approximately 14 um operation, room-temperature performance, and preferred resonant-energy placement. In preferred embodiments, this measured operating point may be used as an acceptance benchmark for the fabricated device family.

In a preferred antenna-coupled embodiment, the zero-bias resonant-tunnelling diode is incorporated into a rectenna pixel having a dipole-type antenna sized for a target operating band near approximately 14 um. Under a disclosed source condition corresponding to a 600 K blackbody and an effective mid-infrared flux condition, the antenna-coupled pixel captures incident radiation and delivers it to the active diode region. Using the preferred responsivity and coupling assumptions described herein, the pixel may produce a preferred modeled short-circuit current, buffered voltage, and output power on the order disclosed in the specification.

This example is treated as a preferred modeled/validated embodiment rather than as a purely demonstrated device-level measurement. In one worked numerical implementation of the preferred rectenna pixel, f_3 dB=1/(2pi×41×0.16e-15)=2.43×10\hat{ }13 Hz, or about 24.3 THz, which exceeds the approximately 21.4 THz target operating frequency. Using Z_a=32 ohms and R_d=41 ohms, eta_match=1−((41−32)/(41+32))\hat{ }2 is about 0.985. For an effective captured power P_capt of about 8.37×10\hat{ }-7 W, I_sc=R0×P_capt is about 7.45 uA. Using a conservative buffered-output efficiency eta_buf of about 0.72, output power P_out is about 0.60 uW, corresponding to a buffered operating point of about 80 mV and about 7.4 uA. These worked values illustrate one preferred operating point and are useful for design, validation, and claim-support purposes. It is useful because it shows how the preferred diode may be translated into a practical pixel-level harvesting structure and because it supports narrower dependent claims directed to antenna-coupled rectenna pixels, pixel-level power generation, and preferred output-conditioning structures.

Barrier thickness may be intentionally varied to shift the resonant sub-band and thereby shift the target operating band. In one alternative embodiment, a two-layer MoS2 barrier places the resonant level at about 140 meV, corresponding to a shorter wavelength band. In the preferred embodiment, a three-layer MoS2 barrier places the resonant level at about 88 meV, corresponding to approximately 14 um. In another alternative embodiment, a four-layer MoS2 barrier places the resonant level at about 60 meV, corresponding to a longer wavelength band.

This example is important because it demonstrates that the disclosed architecture is not restricted to a single exact wavelength, even though the three-layer embodiment is preferred. Rather, the same basic asymmetric resonant-tunnelling diode architecture may be tuned across a family of mid-infrared target bands by varying the barrier layer count. This example should support both broad independent claims and narrower fallback claims directed to particular layer counts, target energies, and wavelength bands.

A plurality of rectenna pixels of the type described in Example 3 may be tiled into an array and electrically combined using selected series, parallel, or mixed interconnect strategies. In one modeled embodiment, a 512×512 pixel array is formed on a common substrate and the outputs of individual pixels are aggregated to provide a larger total output. Depending on the selected interconnect arrangement, the aggregated output may be structured to emphasize total current, total voltage, or a desired combination thereof.

This example is treated as a preferred modeled system embodiment. It preserves support for array-level harvesting and power aggregation while keeping the core inventive identity in the underlying rectifying pixel. It also supports fallback claim sets directed to tiled arrays, output buses, grouped interconnect schemes, and regulated-output interfaces.

A plurality of disclosed rectifying pixels may be arranged in an imaging array and coupled to readout integrated circuitry for passive thermal imaging or wavelength-selective detection. In one downstream embodiment, the array is formed at a selected detector pitch and integrated through a bonding interface to a ROIC or similar readout circuit. The readout circuit may sample per-pixel rectified outputs, buffer those outputs, integrate them over time, or otherwise produce detector or image data.

This example is a downstream embodiment rather than the core invention. It is included to preserve support for detector/readout claim families and continuation paths. The example demonstrates that the disclosed zero-bias rectifier can serve as a detector-plane element without changing its core physical mechanism.

Multiple tuned pixel groups may be arranged so that one group serves as a reference channel and one or more additional groups serve as gas-band channels corresponding to one or more absorption bands of interest. Outputs from the respective groups may be compared, normalized, ratioed, or otherwise processed to generate a gas-presence indication, concentration estimate, or other spectral sensing output. In some embodiments, one portion of the array may also provide harvested or buffered power for the downstream sensing electronics.

This example is a downstream and partly prophetic embodiment. It is included to preserve support for wavelength-grouped sensing arrays and self-powered sensing architectures, but it should remain subordinate to the core zero-bias resonant-tunnelling rectifier.

A tiled rectifying array may be oriented toward a colder effective sky environment while the array remains thermally associated with a warmer local environment. Under such conditions, a net radiative exchange may be presented to the array in a preferred atmospheric-window band, and the array may convert the resulting flux imbalance into usable electrical output. Output may be buffered, regulated, stored, or delivered to downstream electronics.

This example is prophetic and future-oriented. It is included to preserve support for thermoradiative system embodiments and related continuation opportunities, but it should not be confused with the demonstrated device-level embodiments described above.

A design workflow may receive a target wavelength, target energy, target source condition, or target system requirement and, based on that input, select a barrier layer count and/or thickness, evaluate electrode asymmetry, evaluate dynamic resistance and capacitance, evaluate antenna match where applicable, estimate device or array performance, and optionally machine-verify selected relationships associated with the preferred embodiment. The workflow may then issue a design output, acceptance decision, fabrication-ready parameter set, report, or verification artifact.

This example is a preferred verification embodiment and preserves support for CRM claims, software-related claims, design-assistance claims, and verification method claims. It is important, however, that the specification maintain the distinction between formal representation of selected preferred relationships and empirical proof of device operation. The verification workflow supports design rigor and claim architecture, but the physical make-and-use disclosure remains grounded in the disclosed device structures and demonstrated operating results.

The foregoing description shows that the present disclosure is organized around a clear core invention: a zero-bias asymmetric resonant-tunnelling diode in which a few-layer MoS2 barrier and oppositely doped graphene electrodes cooperate to position a quantized resonant sub-band for photon-assisted mid-infrared rectification. The disclosed architecture provides several technical advantages over conventional mid-infrared rectification and detection approaches. The atomically thin active junction reduces capacitance and transit time relative to thicker transport structures. The graphene electrodes support ultrafast carrier transport, while the few-layer MoS2 barrier supplies a quantized resonant tunnelling condition. The built-in electrode asymmetry enables zero-bias rectification rather than requiring an externally applied rectifying bias. The preferred 14 um operating point lies in a practically useful mid-infrared spectral region and, in preferred doctrinal embodiments, is also near E_coh=phi\hat{ }-5. The antenna-coupled pixel architecture permits efficient delivery of incident mid-infrared radiation into the active diode, and the same pixel kernel may be tiled into arrays, detector planes, gas-sensing channels, power-scavenging devices, or thermoradiative systems without changing the identity of the core rectifier. Formal representation and machine verification of selected relationships further provide proof-assisted design discipline for preferred embodiments, while empirical performance remains grounded in fabricated-device structure and measured or modeled electrical and optical parameters. The preferred embodiment uses a three-layer MoS2 barrier to place the resonant condition near about 88 meV and thereby target approximately 14 um radiation, with optional antenna coupling, optional formal verification of selected preferred relationships, and optional downstream output conditioning, array integration, and system-level use.

The disclosure further preserves alternative embodiments, including different barrier layer counts for different target bands, antenna-coupled pixels, tiled arrays, detector/readout implementations, gas-sensing architectures, thermoradiative system embodiments, and verification-assisted design workflows. These embodiments do not replace or obscure the identity of the invention. Rather, they show how the same core resonant zero-bias rectifier may be tuned, packaged, verified, and deployed in different downstream forms.

Those skilled in the art will appreciate that various substitutions, modifications, combinations, rearrangements, and equivalents may be employed without departing from the spirit and scope of the disclosed subject matter. Accordingly, the present disclosure is intended to encompass not only the particular embodiments expressly described herein, but also variations and equivalents that preserve the disclosed asymmetric zero-bias resonant-tunnelling rectification mechanism.

What is claimed is:

1. A zero-bias resonant-tunnelling diode comprising:
a first graphene electrode of a first doping type;
a second graphene electrode of an opposite doping type from the first doping type;
a few-layer MoS2 barrier disposed between the first graphene electrode and the second graphene electrode, the barrier supporting a quantized resonant sub-band at an energy within a mid-infrared photon band;
wherein built-in asymmetry between the first graphene electrode and the second graphene electrode positions the quantized resonant sub-band such that incident mid-infrared photons having energy aligned to the quantized resonant sub-band drive photon-assisted resonant tunnelling through the barrier and generate DC current without external bias.

2. The diode of claim 1, wherein the quantized resonant sub-band is positioned at an energy from 60 meV to 140 meV.

3. The diode of claim 1, wherein the built-in asymmetry exceeds 50 meV.

4. The diode of claim 1, wherein the first graphene electrode is p-doped and the second graphene electrode is n-doped.

5. The diode of claim 1, wherein the barrier comprises a three-layer MoS2 barrier having a thickness from 1.8 nm to 2.0 nm and placing the quantized resonant sub-band near 88 meV.

6. The diode of claim 1, wherein a second graphene monolayer is transferred over the few-layer MoS2 barrier with an angular offset from 25 degrees to 35 degrees relative to a first graphene monolayer to reduce or suppress moire superlattice effects.

7. The diode according to claim 1, wherein the diode has a zero-bias dynamic resistance from 20 ohms to 100 ohms and a junction capacitance less than 0.5 fF, thereby providing a 3 dB cutoff frequency above 20 THz.

8. The diode according to claim 1, wherein the diode provides zero-bias responsivity of at least 8 A/W at 300 K under illumination in a target mid-infrared operating band near 14 um.

9. The diode according to claim 1, wherein the first graphene electrode is chemically p-doped by HNO3 vapor exposure and the second graphene electrode is electrostatically gated through a silicon substrate to provide n-type behavior.

10. The diode of claim 1, wherein the quantized resonant sub-band is aligned within 5 percent of E_coh=phi\hat{ }-5, where phi=(1+sqrt(5))/2.

11. A mid-infrared rectifying system comprising:
a zero-bias resonant-tunnelling diode according to claim 1; and
an antenna coupled to the diode and configured to couple incident mid-infrared radiation into the diode,
wherein the antenna and the diode together form a rectenna pixel that produces DC output without external bias.

12. The system according to claim 11, wherein the antenna comprises a lithographic dipole antenna having a length from 4 um to 8 um and is impedance matched to the diode at a frequency from 15 THz to 30 THz with a coupling efficiency of at least 90 percent.

13. The system according to claim 11, further comprising an output-conditioning circuit configured to buffer, accumulate, level-shift, regulate, charge-pump, or store the DC output produced by the rectenna pixel.

14. The system according to claim 11, wherein the rectenna pixel is included in a tiled array of a plurality of rectenna pixels disposed on a common substrate and electrically coupled through series, parallel, or mixed series-parallel interconnects.

15. The system according to claim 11, wherein the rectenna pixel is included in a 512×512 array positioned to receive mid-infrared radiation from a source at 400 K to 800 K and configured to produce at least 100 mW of continuous DC output through aggregated pixel outputs.

16. A process for rectifying mid-infrared radiation without external bias, the process comprising:
providing a vertical van der Waals resonant-tunnelling structure comprising a first graphene electrode of a first doping type, a second graphene electrode of an opposite doping type, and a few-layer MoS2 barrier disposed between the first graphene electrode and the second graphene electrode, the barrier supporting a quantized resonant sub-band;
illuminating the resonant-tunnelling structure with mid-infrared photons having energy aligned to the quantized resonant sub-band; and
collecting DC current generated by photon-assisted resonant tunnelling through the barrier without applying external bias across the resonant-tunnelling structure.

17. The process according to claim 16, further comprising selecting a barrier layer count or barrier thickness to place the quantized resonant sub-band in a target mid-infrared operating band.

18. A fabrication process for a zero-bias resonant-tunnelling diode, comprising:
transferring a first CVD graphene monolayer onto an insulating substrate;
dry-stamping a few-layer MoS2 barrier onto the first CVD graphene monolayer;
transferring a second CVD graphene monolayer over the few-layer MoS2 barrier;
doping the first CVD graphene monolayer and the second CVD graphene monolayer to establish opposite doping types and a built-in asymmetry across the few-layer MoS2 barrier; and
patterning metal contacts and an impedance-matched antenna by lithographic metal deposition.

19. The system of claim 12, wherein the rectenna pixel has an antenna impedance Z_a and a diode dynamic input resistance R_d at an operating frequency, and a reflection coefficient magnitude at an interface between the antenna and the diode is less than 0.15.

20. The system of claim 15, wherein the 512×512 array is interconnected as 128 series-connected pixels in each of 2048 parallel-connected strings to provide a DC output voltage of at least 5 volts.
